(19) United States
(12) Patent Application Publication
(10) Pub. No.: US 2005/0201056 A1
(43) Pub. Date: Sep. 15, 2005

(54) Heat-dissipating device for a computer casing

(76) Inventor: Hao-Cheng Lin, Taipei City (TW)

Correspondence Address: CHRISTENSEN, O'CONNOR, JOHNSON, KINDNESS, PLLC, 1420 FIFTH AVENUE, SUITE 2800, SEATTLE, WA, 98101-2347, US

(21) Appl. No.: 10/797,970

(22) Filed: Mar. 11, 2004

(51) Int. Cl. H05K 7/20; G06F 1/16

(52) U.S. Cl. 361/695; 162/121; 165/80.3

(57) ABSTRACT

A heat-dissipating device is used to dissipate heat generated by a component in a computer casing, and includes a flexible tubular conduit and a fan unit. The tubular conduit is adapted to be disposed in the computer casing, and has a first end adapted to be connected to the computer casing such that the first end of the tubular conduit is registered with and communicates fluidly with a vent hole in the computer casing, and a second end opposite to the first end. The fan unit is mounted on the second end of the tubular conduit, and is adapted to be mounted in the computer casing such that the fan unit confronts the component in the computer casing. The fan unit is operable so as to generate air currents that flow through the tubular conduit for cooling the component in the computer casing.

### BACKGROUND OF THE INVENTION

1. Field of the Invention

The invention relates to a heat-dissipating device, more particularly to a heat-dissipating device for a computer casing.

2. Description of the Related Art

With the increase in the operating speed of a central processing unit (CPU) on a computer motherboard, the power consumption of components in a computer casing, such as a display card (VGA card), a game card, a hard disk drive, etc., has also increased considerably in recent years, which results in a high temperature inside the computer casing after a period of use. As such, there is a need to install a large electric fan directly on the computer casing so as to lower the temperature therein. In addition, a small electric fan is mounted on the CPU for dissipating the heat generated thereby. However, since the CPU is disposed on the computer motherboard, the small electric fan can only utilize the hot air inside the computer casing for cooling the CPU. The heat-dissipating effect of the small electric fan is thus not satisfactory.

Furthermore, while the large electric fan can draw cool air into the computer casing for lowering the temperature therein, dust is brought into the computer casing at the same time, thereby resulting in a dirty environment inside the computer casing.

### SUMMARY OF THE INVENTION

Therefore, the object of the present invention is to provide a heat-dissipating device for a computer casing that can overcome the aforesaid drawbacks of the prior art.

According to the present invention, a heat-dissipating device is adapted for dissipating heat generated by a component in a computer casing that is formed with a vent hole. The heat-dissipating device comprises a flexible tubular conduit and a fan unit. The tubular conduit is adapted to be disposed in the computer casing, and has a first end adapted to be connected to the computer casing such that the first end of the tubular conduit is registered with and communicates fluidly with the vent hole, and a second end opposite to the first end. The fan unit is mounted on the second end of the tubular conduit, and is adapted to be mounted in the computer casing such that the fan unit confronts the component in the computer casing. The fan unit is operable so as to generate air currents that flow through the tubular conduit for cooling the component in the computer casing.

### BRIEF DESCRIPTION OF THE DRAWINGS

Other features and advantages of the present invention will become apparent in the following detailed description of the preferred embodiments with reference to the accompanying drawings, of which:

FIG. 1 is a schematic side view to illustrate the interior of a computer casing that incorporates the first preferred embodiment of a heat-dissipating device according to the present invention;

FIG. 2 is a schematic electrical circuit diagram of a detecting circuit of the first preferred embodiment; and

FIG. 3 is a perspective view to illustrate a computer casing that incorporates the second preferred embodiment of a heat-dissipating device according to the present invention.

### DETAILED DESCRIPTION OF THE PREFERRED EMBODIMENTS

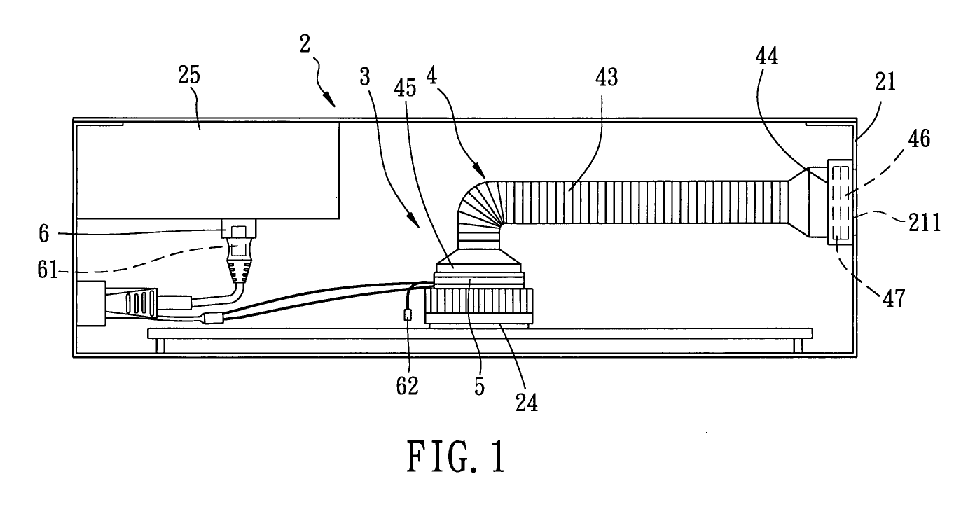

Referring to FIG. 1, the first preferred embodiment of a heat-dissipating device 3 according to the present invention is shown to be adapted for dissipating heat generated by a component 24 in a computer casing 21 of a computer 2. The computer casing 21 has one side formed with a vent hole 211. The heat-dissipating device 3 comprises a flexible tubular conduit 4 and a fan unit 5.

The tubular conduit 4 is adapted to be disposed in the computer casing 21, and includes a flexible tube body 43 having a first end 44 adapted to be connected to the computer casing 21 such that the first end 44 of the tube body 43 is registered with and communicates fluidly with the vent hole 211, and a second end 45 opposite to the first end 44.

The fan unit 5 is mounted on the second end 45 of the tube body 43, and is adapted to be disposed in the computer casing 21 such that the fan unit 5 confronts the component 24 in the computer casing 21. The fan unit 5 is operable so as to generate air currents that flow through the tubular conduit 4 for cooling the component 24 in the computer casing 21. In this embodiment, the fan unit 5 is operable in a known manner such that cool air is drawn into the tubular conduit 4 via the first end 44 of the tube body 43 and such that the cool air in the tubular conduit 4 is released via the second end 45 of the tube body 43 and is directed to the component 24 so as to lower the temperature of the same.

In this embodiment, the tubular conduit 4 further has an air filter 46 and a fragrance dispenser 47 mounted removably at the first end 44 of the tube body 43. Preferably, the fragrance dispenser 47 is disposed inwardly with respect to the air filter 46. The air filter 46 is used to filter out dust when cool air is drawn into the tubular conduit 4, thereby maintaining a clean environment inside the computer casing 21. By virtue of the fragrance dispenser 47, a fragrant smell will diffuse out of the computer casing 21 when the fan unit 5 operates.

The heat-dissipating device 3 of this embodiment further comprises a control unit 6 mounted in the computer casing 21. The control unit 6 includes a detecting circuit 61 that is coupled to the fan unit 5. The detecting circuit 61 includes a temperature sensor 62 for detecting the temperature of air inside the computer casing 21. In this embodiment, the temperature sensor 62 is a thermistor, and is mounted in the computer casing 21 adjacent to the component 24. In practice, the temperature sensor 62 can be mounted so as to establish direct contact with the component 24.

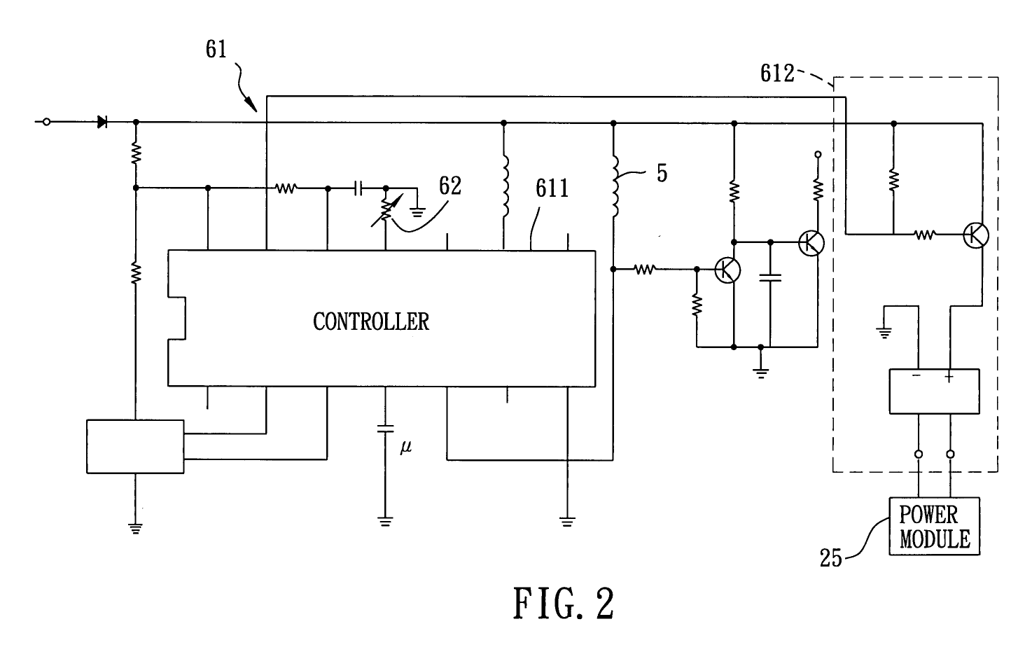

With further reference to FIG. 2, the detecting circuit 61 can be configured to perform different operations according to the temperature detected by the temperature sensor 62. For example, a controller 611 of the detecting circuit 61 can be configured to control the fan unit 5 to operate at an operating speed that corresponds to the temperature detected by the temperature sensor 62. That is, the controller 611 can control the fan unit 5 to increase its operating speed to enhance the heat-dissipating effect when necessary. In addition, the controller 611 can be configured to control generation of an audible or visible alarm output when the temperature detected by the temperature sensor 62 exceeds a predetermined threshold.

In this embodiment, the detecting circuit 61 further includes a relay unit 612 that is coupled to the controller 611. When the temperature detected by the temperature sensor 62 reaches an upper temperature limit, the controller 611 issues a deactivate command to the relay unit 612. In response to the deactivate command, the relay unit 612 disables a power module 25 inside the computer casing 21, thereby shutting down the computer 2 to protect the latter from damage due to overheating, such as when the fan unit 5 malfunctions.

Based on actual test results, under a room temperature of 20° C., the temperature inside the computer casing 21 reached 40° C. while that of a CPU (i.e., the component 24) reached 80° C. thirty minutes after the computer 2 is turned on when a conventional heat-dissipating fan operates at 3100 rpm. In contrast, under the same room temperature, when the heat-dissipating device 3 of this invention is in use, and the fan unit 5 of the heat-dissipating device 3 operates at the same speed of 3100 rpm, the temperature inside the computer casing 21 reached only 21° C. while that of the CPU (i.e., the component 24) reached only 70° C. thirty minutes after the computer 2 is turned on. The temperature values are significantly lower as compared to those achieved by the prior art.

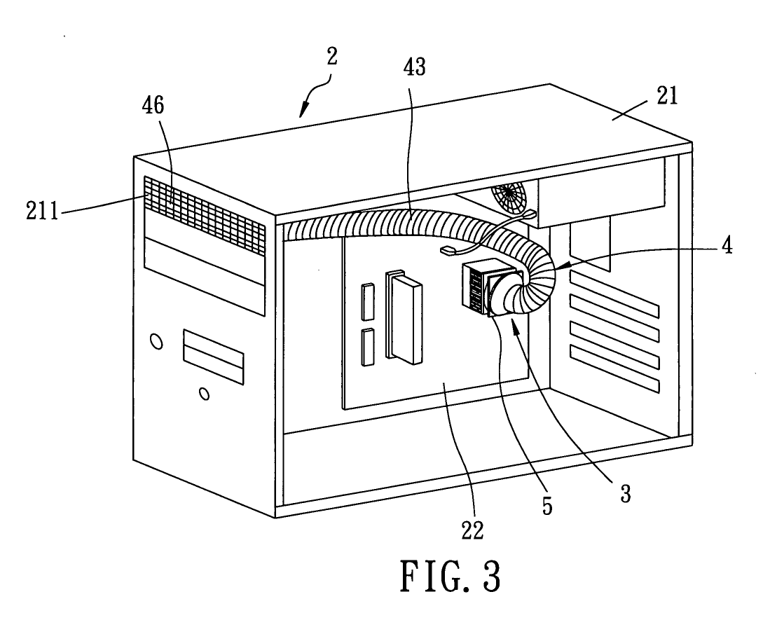

FIG. 3 illustrates another computer 2 having a computer casing 21 that incorporates the second preferred embodiment of a heat-dissipating device 3 according to the present invention. In this embodiment, the computer casing 21 of the computer 2 is a stand-type casing with a computer motherboard 22 mounted uprightly therein. The computer casing 21 further has a front side formed with a mounting hole 211 that is allocated for mounting a disk drive. The mounting hole 211 serves as the vent hole in this embodiment. Thus, one end of the tube body 43 of the flexible tubular conduit 4 of the heat-dissipating device 3 is connected to the front side of the computer casing 21 so as to communicate fluidly with the mounting hole 211. In addition, unlike the previous embodiment, the air filter 46 maybe configured for mounting on the front side of the computer casing 21 at the mounting hole 211 instead of the tube body 43 of the tubular conduit 4.

While the present invention has been described in connection with what is considered the most practical and preferred embodiments, it is understood that this invention is not limited to the disclosed embodiments but is intended to cover various arrangements included within the spirit and scope of the broadest interpretation so as to encompass all such modifications and equivalent arrangements.

1. A heat-dissipating device adapted for dissipating heat generated by a component in a computer casing, the computer casing being formed with a vent hole, said heat-dissipating device comprising:
a flexible tubular conduit adapted to be disposed in the computer casing, and having a first end adapted to be connected to the computer casing such that said first end of said tubular conduit is registered with and communicates fluidly with the vent hole, and a second end opposite to the first end; and
a fan unit mounted on said second end of said tubular conduit and adapted to be mounted in the computer casing such that said fan unit confronts the component in the computer casing, said fan unit being operable so as to generate air currents that flow through said tubular conduit for cooling the component in the computer casing.

2. The heat-dissipating device as claimed in claim 1, wherein said fan unit is operable such that air is drawn into said tubular conduit via said first end of said tubular conduit and such that the air in said tubular conduit is released via said second end of said tubular conduit.

3. The heat-dissipating device as claimed in claim 1, wherein said tubular conduit further has an air filter mounted removably at one of said first and second ends thereof.

4. The heat-dissipating device as claimed in claim 1, wherein said tubular conduit further has a fragrance dispenser mounted at one of said first and second ends thereof.

5. The heat-dissipating device as claimed in claim 1, further comprising a detecting circuit that includes a temperature sensor adapted for detecting temperature inside the computer casing.

6. The heat-dissipating device as claimed in claim 5, wherein said temperature sensor is a thermistor.

7. The heat-dissipating device as claimed in claim 5, wherein said temperature sensor is adapted to be mounted in the computer casing adjacent to the component.

8. The heat-dissipating device as claimed in claim 5, wherein said detecting circuit is coupled to said fan unit and is configured to control operating speed of said fan unit according to the temperature inside the computer casing.

9. The heat-dissipating device as claimed in claim 5, wherein said detecting unit is configured to generate an alarm output according to the temperature inside the computer casing.

10. The heat-dissipating device as claimed in claim 5, wherein said detecting unit is configured to generate a deactivate command according to the temperature inside the computer casing.
